(19) United States
(12) Patent Application Publication
(10) Pub. No.: US 2013/0215562 A1
(43) Pub. Date: Aug. 22, 2013

(54) SCREWING STRUCTURE FOR CASING AND ELECTRONIC DEVICE PROVIDED WITH SAME

(71) Applicant: SANYO Electric Co., Ltd., (US)

(72) Inventor: Daizo Kobayashi, Hirakata-shi (JP)

(73) Assignee: SANYO Electric Co., Ltd., Osaka (JP)

(21) Appl. No.: 13/770,598

(22) Filed: Feb. 19, 2013

(30) Foreign Application Priority Data
Feb. 17, 2012 (JP) 2012-032760

(51) Int. Cl. H05K 5/02; F16B 35/00

(52) U.S. Cl. CPC H05K 5/0217; F16B 35/00
USPC 361/679.01; 411/378

(57) ABSTRACT

A screwing structure for a casing according to the present invention includes: a first casing; a second casing; and a screw for integrating the first casing and the second casing with each other; wherein the first casing includes a boss having a first screw hole, into which the screw is screwed, and a fitting piece projecting from the peripheral edge of the boss, and wherein the second casing includes a second screw hole formed therethrough at a position opposite to the first screw hole, the screw being screwed through the second screw hole, and a fitting receiver in abutment against the fitting piece in a tightly turning direction of the screw.

### CROSS-REFERENCE TO RELATED APPLICATION

Japanese Patent Application No. 2012-32760 filed on Feb. 17, 2012, on which the priority right of the present application is based, is incorporated herein by reference.

### BACKGROUND OF THE INVENTION

1. Field of the Invention

The present invention relates to a screwing structure for tightening casings to each other and an electronic device provided with the same. More particularly, the present invention relates to a screwing structure capable of suppressing deformation of a casing at the time of screwing and an electronic device provided with the same.

2. Description of Related Art

In an electronic device such as a digital camera, an outside housing is constituted of a front casing and a rear casing, and further, an inner casing is housed inside. These casings are tightened to each other by screwing.

Such an electronic device is required to be reduced in thickness. Each of the casings made of a resin material also is required to be reduced in thickness.

However, as a result of the reduction of the thickness of the casing, a boss, to which a screw is screwed, cannot secure sufficient strength. When the screw is tightened, the casing in the vicinity of the boss may be possibly flexed in a tightly turning direction of the screw by torque generated at the time of tightening, to be thus deformed.

In general, a plurality of ribs are formed along the boss in order to enhance the strength in the vicinity of the boss. However, in the case where a channel of a wiring or terminal for connecting a power source or outside equipments is needed, ribs or the like can not be formed, thereby making it difficult to reinforce the boss.

An object of the present invention is to provide a screwing structure for a casing capable of suppressing deformation of a boss by screwing even at a portion at which a reinforcing rib can be hardly formed, and an electronic device provided with the same.

### SUMMARY OF THE INVENTION

A screwing structure for a casing according to the present invention includes:

a first casing;

a second casing; and

a screw for integrating the first casing and the second casing with each other;

wherein the first casing includes a boss having a first screw hole, into which the screw is screwed, and a fitting piece projecting from a peripheral edge of the boss, and

wherein the second casing includes a second screw hole formed therethrough at a position opposite to the first screw hole, the screw being screwed through the second screw hole, and a fitting receiver in abutment against the fitting piece in a tightly turning direction of the screw.

### BRIEF DESCRIPTION OF THE DRAWINGS

FIG. 1 is a perspective view showing a digital camera provided with a screwing structure for a casing in one preferred embodiment according to the present invention, as slantwise viewed from below;

FIG. 2 is a bottom view showing the digital camera shown in FIG. 1;

FIG. 3 is an exploded perspective view showing a front casing and a rear casing detached from the front casing;

FIG. 4 is a partly enlarged cross-sectional view showing the digital camera shown in FIG. 1, taken along a line IV-IV passing through a boss; and

FIG. 5 is an enlarged cross-sectional perspective view showing the digital camera shown in FIG. 1, taken along a line V-V passing through a retaining rib.

### DETAILED DESCRIPTION OF THE PREFERRED EMBODIMENT

A description will be given below of a digital camera 10 as an electronic device, to which the present invention is applied. In each of the attached drawings, electric parts for the digital camera 10 will be omitted for the sake of easy understanding.

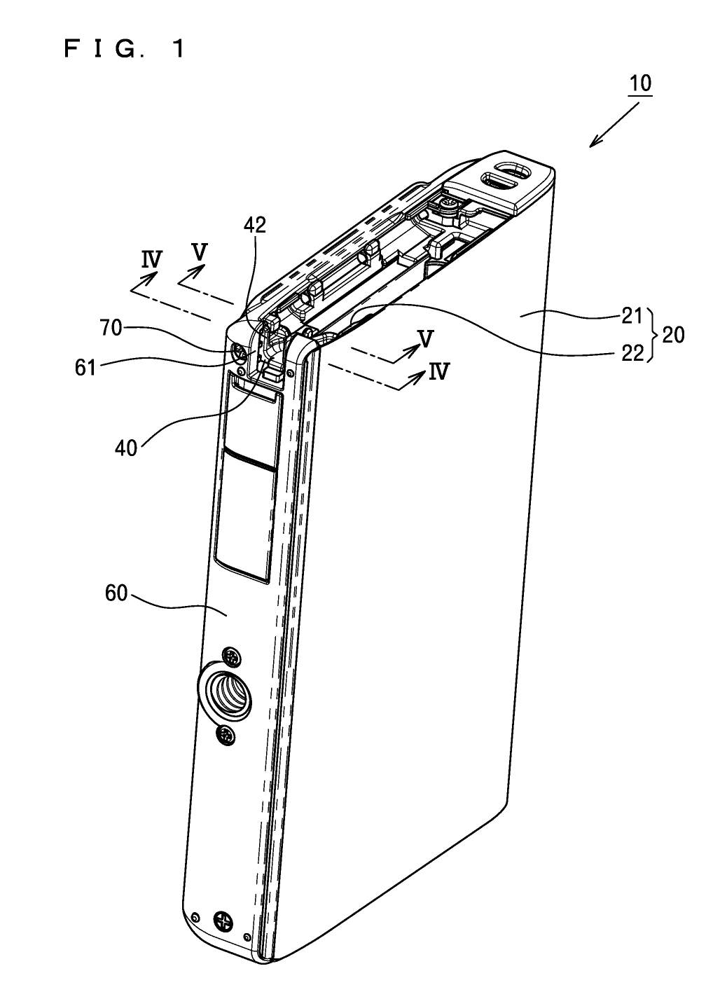

As shown in FIGS. 1 to 5, the digital camera 10 is surrounded by a resin front casing 20 and a resin rear casing 60 (corresponding to a second casing according to the present invention), wherein the casings serve as the exterior and support electronic parts housed therein.

The front casing 20 is constituted of a decorative panel 21 disposed on an outer side and an inner casing 22 (corresponding to a first casing according to the present invention) disposed inside the decorative panel 21.

The decorative panel 21 and the inner casing 22 are integrated with each other by means of bonding, sticking, screwing, fitting, or the like.

The front casing 20 and the rear casing 60 are tightened to each other by fitting with a hook mechanism or screwing with a screw 70.

The digital camera 10 includes a lens, a flash, a shutter button, a power source button, terminals for connecting an HDMI and a USB for outside outputting, an outside power source connecting terminal, and a connector for a battery or a memory, so as to exhibit its function. These component parts are operated or visually recognized from the outside or covered with a cover or the like, and can be accessed from the outside, as required.

For example, a DC coupler, not shown, connected to an outside power source is contained in a recess designated at reference numeral 61 in FIGS. 1 to 3. A wiring of the DC coupler extends to the inside of a housing through the recess 61.

Incidentally, the recess 61 may be closed by a cover, not shown, when the outside power source is not needed to be connected.

In the present preferred embodiment, a screwing structure for the casing according to the present invention is adopted at the recess 61. It is to be understood that the present invention may be applied to other portions than the recess 61.

The recess 61 is formed by recessing the outer surface of the rear casing 60. A second screw hole 62 is formed in the vicinity of the recess 61, more specifically, behind the recess 61 through the rear casing 60. A screw 70 is inserted into the second screw hole 62, so that the rear casing 60 is tightened to the inner casing 22.

At the inner casing 22, a rod- or plate-like arm 40 projects rearward at a position corresponding to the recess 61 of the rear casing 60. A cylindrical boss 50 having a first screw hole 51 formed at a position corresponding to the second screw hole 62 of the rear casing 60 is disposed at a tip of the arm 40.

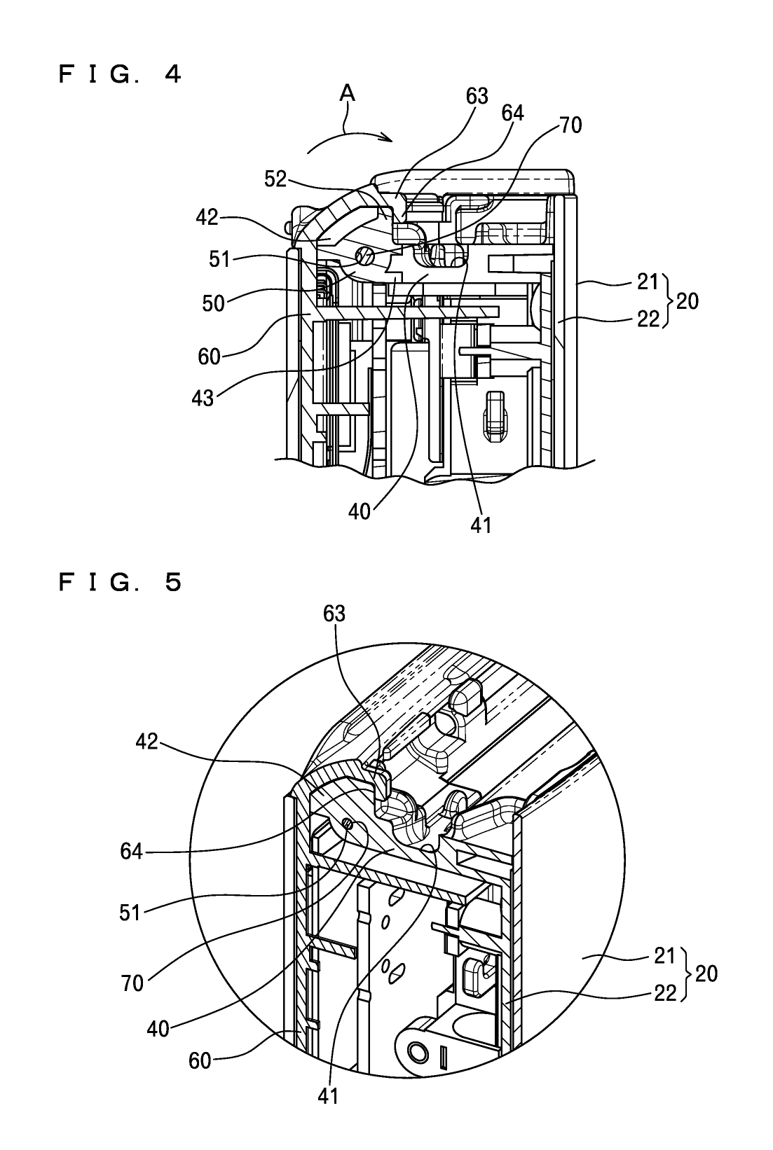

A cutout 41 is formed at the arm 40, so that a wiring or terminal for the DC coupler is inserted and disposed at a position opposite to the recess 61. The arm 40 is narrowed. In other words, the arm 40 is flexed at the position of the cutout 41, and thus, is readily deformed. When the boss 50 receives torque of the screw 70 in a tightly turning direction, the arm 40 is flexed by the torque, so that the boss 50 per se is deviated in a direction indicated by an arrow A in FIG. 4.

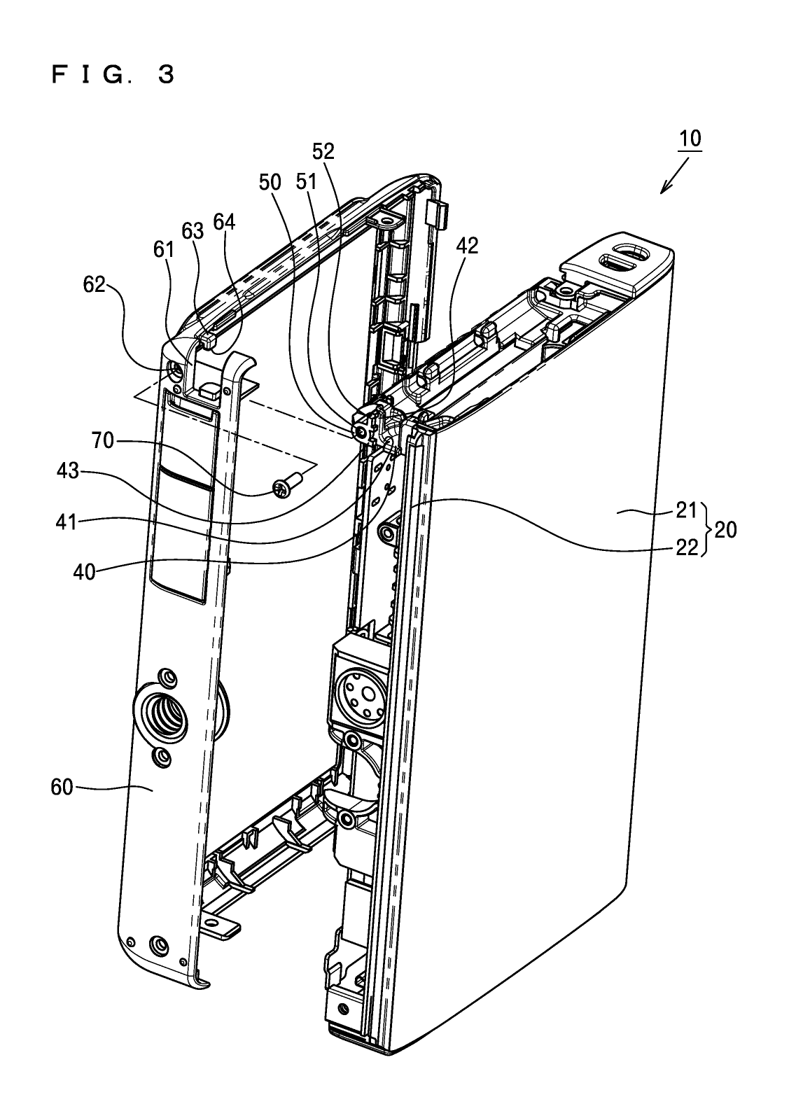

In view of the above, as shown in FIGS. 3 and 4, according to the present invention, a fitting piece 52 extending toward the rear casing 60 projects from the peripheral edge of the boss 50, and further, a fitting receiver 63 projects at a position in abutment with the fitting piece 52 in the tightly turning direction (indicated by the arrow A in FIG. 4) at the time of tightening with the screw 70 in the rear casing 60.

Here, in order to enhance a fixing strength of the boss 50 with respect to the arm 40, the arm 40 has a retaining rib 42 having a tip whose diameter is enlarged and the boss 50 is mounted on the retaining rib 42 in the preferred embodiment shown in FIGS. 4 and 5. The outer periphery of the retaining rib 42 is formed into a shape in conformity with the inner surface of the rear casing 60, and therefore, it also retains the rear casing 60.

In the preferred embodiment shown in the drawings, in order to enhance the strength of the fitting piece 52, the fitting piece 52 is integrally molded in such a manner as to be continuous to the retaining rib 42.

Moreover, in order to suppress the flexure or the like of the boss 50, one or more reinforcing ribs 43 are interposed between the peripheral edge of the boss 50 and the retaining rib 42.

The fitting receiver 63 of the rear casing 60 may exemplify a hooked member projecting from the vicinity of the peripheral edge of the rear casing 60. The fitting receiver 63 is provided with a pawl piece 64 having a tip bent inward in such a manner as to abut against the fitting piece 52 of the inner casing 22 in the tightly turning direction of a screw 70 (indicated by the arrow A in FIG. 4) in the state in which the front casing 20 and the rear casing 60 are fitted to each other, as shown in FIG. 1.

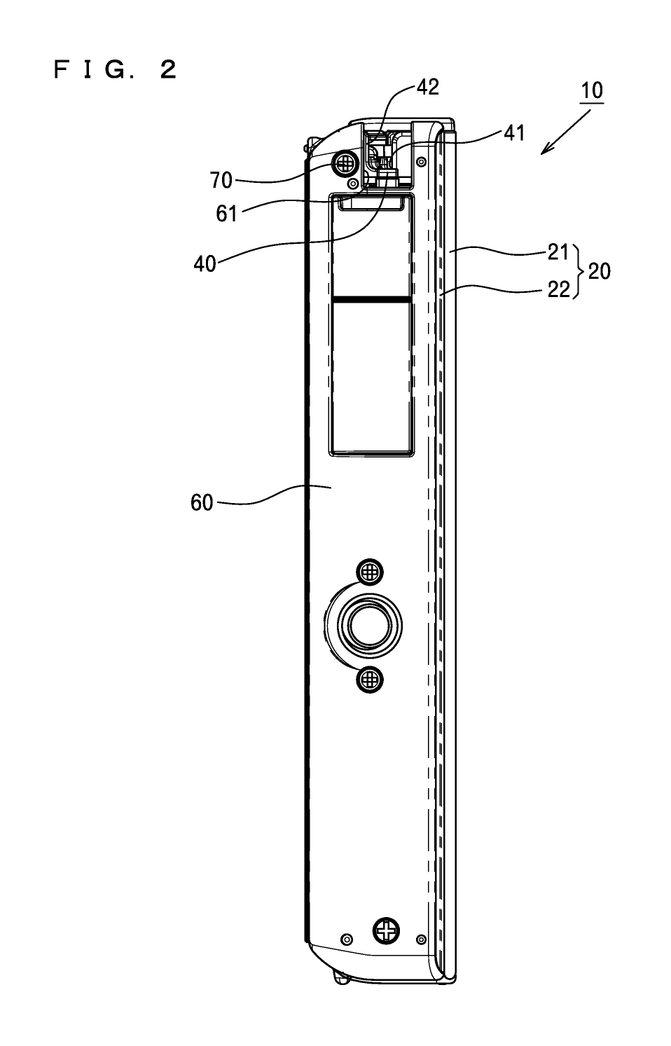

In the screwing structure for the casing in the digital camera 10 having the above-described configuration, in the state shown in FIG. 3, the front casing 20 and the rear casing 60 are fitted to each other, as shown in FIGS. 1 and 2, so that the screw 70 is inserted into the second screw hole 62 (see FIG. 3) of the rear casing 60 to be thus screwed to the first screw hole 51 of the boss 50 of the inner casing 22. Consequently, the inner casing 22 is tightened to the rear casing 60.

At this time, when the screw 70 is turned in the tightly turning direction indicated by the arrow A in FIG. 4, the torque acts on the boss 50 in the tightly turning direction, and therefore, the arm 40 receives such force as to flex and deform at the narrow position where the cutout 41 is formed. However, when the torque acts on the boss 50 in the tightly turning direction, and then, the boss 50 is to follow and be turned in the tightly turning direction, the fitting piece 52 abuts against the fitting receiver 63, thereby restricting the boss 50 from being turned.

More specifically, the fitting piece 52 abuts against the pawl piece 64 of the fitting receiver 63, thereby restricting the boss 50 from being turned in the tightly turning direction, as shown in FIG. 4.

As described above, the torque acting on the boss 50 is received in abutment of the fitting piece 52 against the fitting receiver 63, thereby preventing the boss 50 from being turned. As a consequence, a reinforcing structure for the arm 40 such as a reinforcing rib can be omitted or simplified with respect to the boss 50.

Moreover, since the boss 50 is restricted from being turned in the tightly turning direction, almost no force for flexing or deforming acts on the arm 40. Therefore, the arm 40 can be reduced in thickness or width, and further, the inner casing 22 serving as the first casing can be reduced in thickness and the digital camera 10 using the inner casing 22 can be reduced in size and thickness.

Additionally, the cutout 41 or a hole is formed at the arm 40, and therefore, the degree of freedom of a design of the inner casing 22 can be increased, thus readily securing a channel for a wiring or a terminal.

The digital camera 10 exemplifies the electronic device and the recess 61 for the DC coupler embodies the screwing structure according to the present invention in the above-described preferred embodiment. However, it is to be understood that the screwing structure for the casing according to the present invention can be applied to devices requiring miniaturization and thinness such as a cellular phone, a smart phone, a music player, and a tablet terminal. In addition, the screwing structure for the casing according to the present invention may be applied to any portions other than that in the above-described preferred embodiment.

The present invention is utilizable for the screwing structure for the casing capable of suppressing the deformation of the boss by tightening with the screw even at a portion where a reinforcing rib for the casings is hardly formed, and the electronic device provided with the same.

What is claimed is:

1. A screwing structure for a casing comprising:
a first casing;
a second casing; and
a screw for integrating the first casing and the second casing with each other;
the first casing including a boss having a first screw hole, into which the screw is screwed, and a fitting piece projecting from the peripheral edge of the boss, and
the second casing including a second screw hole formed therethrough at a position opposite to the first screw hole, the screw being screwed through the second screw hole, and a fitting receiver in abutment against the fitting piece in a tightly turning direction of the screw.

2. The screwing structure for a casing according to claim 1, wherein the boss is formed at a tip of a rod- or plate-like arm projecting from the first casing.

3. The screwing structure for a casing according to claim 2, wherein a cutout, into which a connecting wiring or terminal is inserted, is formed at the arm.

4. An electronic device provided with the screwing structure for a casing according to claim 1.
